(19) United States
(12) Patent Application Publication
(10) Pub. No.: US 2009/0039366 A1
(43) Pub. Date: Feb. 12, 2009

(54) Semiconductor light-emitting device with high heat-dissipation efficiency and method for fabricating the same

(75) Inventor: Shu-Wei Chiu, Taichung (TW)

Correspondence Address: BIRCH STEWART KOLASCH & BIRCH, PO BOX 747, FALLS CHURCH, VA, 22040-0747, US

(73) Assignee: HUGA OPTOTECH INC.

(21) Appl. No.: 12/010,188

(22) Filed: Jan. 22, 2008

(30) Foreign Application Priority Data
Aug. 8, 2007 (TW) 096129132

(51) Int. Cl. H01L 33/00

(52) U.S. Cl. 257/98; 438/32; 257/E33.068

(57) ABSTRACT

The invention discloses a semiconductor light-emitting device and a method of fabricating the same. The semiconductor light-emitting device according to the invention includes a substrate, a multi-layer structure, a first electrode structure, and a second electrode structure. The substrate has an upper surface and a lower surface. The substrate therein includes at least one formed-through hole which is filled with a thermally conductive material. The multi-layer structure is formed on the upper surface of the substrate and includes a light-emitting region. The first electrode structure is formed on the multi-layer structure, and the second electrode structure is formed on the lower surface of the substrate. In particular, the heat generated during the operation of the semiconductor light-emitting device is conducted to the thermally conductive material and then is dissipated therefrom.

### BACKGROUND OF THE INVENTION

1. Field of the Invention

The present invention relates to a semiconductor light-emitting device, and more particularly, relates to a semiconductor light-emitting device with high heat-dissipation efficiency.

2. Description of the Prior Art

Nowadays, semiconductor light-emitting devices, such as Light Emitting Diodes (LEDs), have been used in a wide variety of applications, e.g., key systems, back light modules of mobile phone monitor, illuminating systems of vehicles, decorated lamps, and remote controls

LEDs can be distinguished as blue and green light LEDs and red and yellow light LEDs according to colors of emitting source. The electrodes of the blue and green light LED are configured at the same side of the LED, and the electrodes of the red light and yellow light LED are configured at two sides of the LED (i.e., AlGaInP LEDs). Due to functions and cost, the development of AlGaInP LEDs has become a trend.

Please refer to FIG. 1A. FIG. 1A is a schematic diagram illustrating an AlGaInP LED in the prior art. As shown in FIG. 1, the LED includes a GaAs substrate 1, a multi-layer reflector 2, a N-type semiconductor layer 3, a multiple quantum well layer 4, a P-type semiconductor layer 5, a window layer 6, a positive electrode 7 and a negative electrode 8. The advantage of the LED is lower cost, but the defect is bad heat-dissipation.

Please refer to FIG. 1B. FIG. 1B is a schematic diagram illustrating another AlGaInP LED in the prior art. As shown in FIG. 1B, the LED includes a Si substrate 11, a metal reflector 12, a P-type semiconductor layer 13, a multiple quantum well layer 14, a N-type semiconductor layer 15, a positive electrode 16 and a negative electrode 17. Compared to the LED in FIG. 1A, the advantage of this LED is better heat-dissipation but higher cost.

With the development of technique, the illumination of LEDs is getting higher and higher. Yet, at the same time, the heat generated is increased and further influences the reliability and the lifetime of LEDs. Therefore, developing an efficient method for dissipating heat of LEDs from the inside to the outside has become an important issue.

Therefore, the major scope of the invention is to provide a semiconductor light-emitting device with high heat-dissipation efficiency to solve the above-mention problems.

### SUMMARY OF THE INVENTION

A scope of the present invention is to provide a semiconductor light-emitting device and a method for fabricating the same.

According to an embodiment of the invention, the semiconductor light-emitting device includes a substrate, a multi-layer structure, a first electrode structure and a second electrode structure.

The substrate has an upper surface and a lower surface. The substrate therein includes at least one formed-through hole, wherein the at least one formed-through hole is filled with a thermal conductive material. The multi-layer structure is formed on the upper surface of the substrate and includes a light-emitting region. The first electrode structure is formed on the multi-layer structure. The second electrode structure is formed on the lower surface of the substrate. Particularly, the heat generated during the operation of the semiconductor light-emitting device is conducted to the thermal conductive material and then is dissipated therefore.

According to another embodiment of the invention, a method for fabricating a semiconductor light-emitting device is provided.

Firstly, a substrate with an upper surface and a lower surface is prepared.

Secondly, a multi-layer structure including a light-emitting region is formed on the upper surface of the substrate.

Thirdly, a first electrode structure is formed on the multi-layer structure. Fourthly, at least one formed-through hole is formed in the substrate.

Fifthly, the at least one formed-through hole is filled with thermal conductive material.

Finally, a second electrode structure is formed on the lower surface of the substrate.

Particularly, the heat generated during the operation of the semiconductor light-emitting device is conducted to the thermal conductive material and then is dissipated therefrom.

Compared with the prior art, the heat generated during the operation of the semiconductor of the invention is conducted to the outside via the thermal conductive material, which is a more efficient method, Therefore, the reliability and the lifetime of the semiconductor light-emitting device can be improved. The light-emitting efficiency of the semiconductor light-emitting device can be raised according to the property of the thermal conductive material. Furthermore, the semiconductor light-emitting device of the invention can generate an advantage of low cost.

The advantage and spirit of the invention may be understood by the following recitations together with the appended drawings.

### BRIEF DESCRIPTION OF THE APPENDED DRAWINGS

FIG. 1A is a schematic diagram illustrating an AlGaInP LED in the prior art.

FIG. 1B is a schematic diagram illustrating another AlGaInP LED in the prior art.

FIG. 2 is a section view illustrating a semiconductor light-emitting device according to an embodiment of the invention.

FIG. 3 is a schematic diagram illustrating the current direction after electrifying the semiconductor light-emitting device according to the invention.

FIG. 4A to FIG. 4F are section views illustrating a method for fabricating a semiconductor light-emitting device according to another embodiment of the invention.

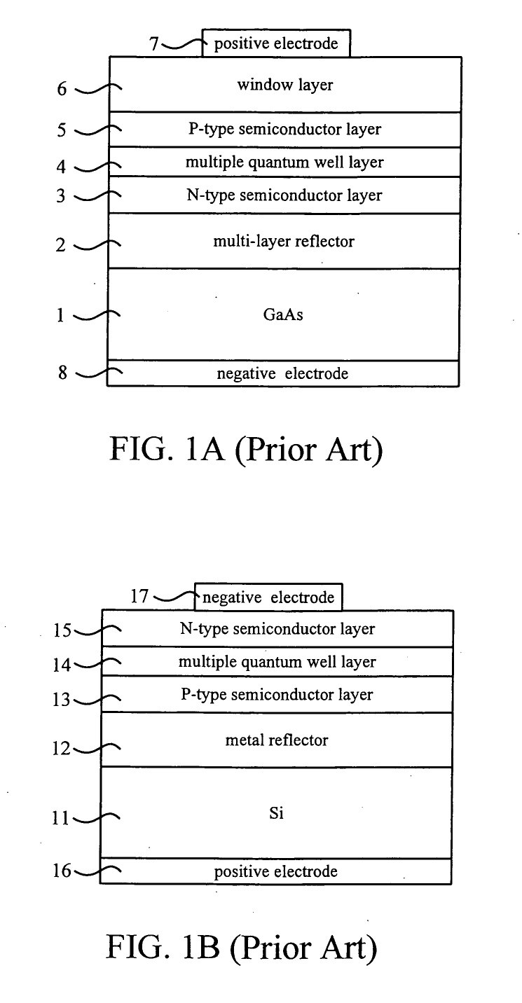

### DETAILED DESCRIPTION OF THE INVENTION

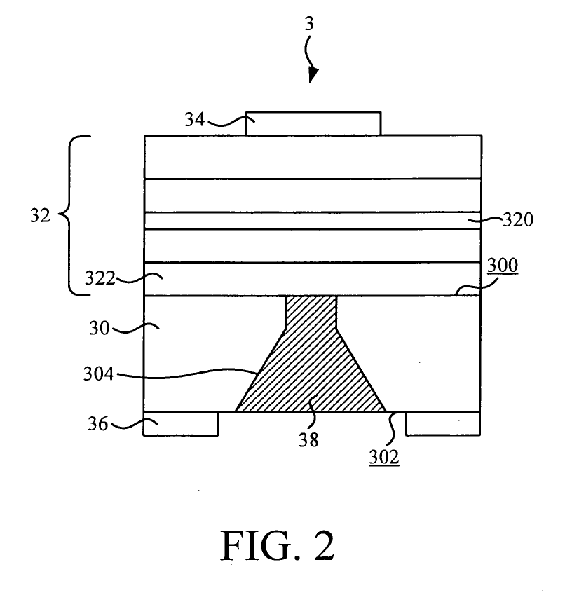

Please refer to FIG. 2. FIG. 2 is a section view illustrating a semiconductor light-emitting device 3 according to an embodiment of the invention. In the embodiment, the semiconductor light-emitting device 3 is, but not limited to, a Light Emitting Diode (LED).

The semiconductor light-emitting device 3 includes a substrate 30, a multi-layer structure 32, a first electrode structure 34 and a second electrode structure 36.

In practice, the substrate 30 can be SiO₂, Si, Ge, GaN, GaAs, GaP, AlN, sapphire, spinnel, Al₂O₃, SiC, ZnO, MgO, LiAlO₂, LiGaO₂, or MgAl₂O₄.

The substrate 30 has an upper surface 300 and a lower surface 302. The substrate 30 therein includes at least one formed-through hole 304, and the at least one formed-through hole 304 can be filled with a thermal conductive material 38. In practice, the number and the positions of formed-through holes 304 can be designed according to the practical requirements. In the embodiment, the substrate 30 includes, but not limited to, one formed-through hole 304.

In an embodiment, the at least one formed-hole 304 can be formed by a dry etching process or a wet etching process.

In practice, the thermal conductive material 38 can be an electrically conductive or an electrically insulated material. For example, the thermal conductive material 38 can be, but not limited to, metal, ceramics, thermal conductive glue, or thermal conductive paste.

The effect of the thermal conductive material 38 is that the heat generated during the operation of the semiconductor light-emitting device 3 can be conducted to the thermal conductive material 38 and dissipated therefrom. Because the heat can be dissipated, in a more efficient method, to the outside from the semiconductor light-emitting device 3 via the thermal conductive material 38, the reliability and the lifetime of the semiconductor conductive material 3 are then improved.

The multi-layer structure 32 is formed on the upper surface 300 of the substrate 30 and includes a light-emitting region 320. The first electrode structure 34 is formed on the multi-layer structure 32. The second electrode structure 36 is formed on the lower surface 302 of the substrate 30.

The bottom-most layer 322 of the multi-layer structure 32 can be a multi-layer reflective layer. In an embodiment, the multi-layer reflective layer is a Distributed Bragg Reflector (DBR).

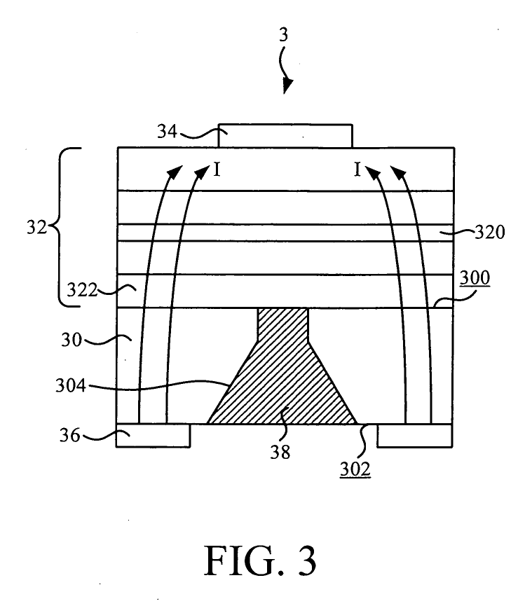

In an embodiment, if the thermal conductive material 38 is an electrically insulated material (such as ceramics), please refer to FIG. 3. FIG. 3 is a schematic diagram illustrating the current direction after electrifying the semiconductor light-emitting device 3 according to the invention.

After electrifying the semiconductor light-emitting device 3, the current concentrates at two sides of the semiconductor light-emitting device 3 for transmission, which makes two sides of the light-emitting region to emit light, so as to raise light-emitting efficiency of the semiconductor light-emitting device 3. In one word, the direction of the above-mentioned current can raise current blocking effect to improve light-emitting efficiency of the semiconductor light-emitting device 3. Therefore, if the thermal conductive material 38 is an electrical insulated material, not only heat-dissipation efficiency but also light-emitting efficiency of the semiconductor light emitting device 3 can be raised.

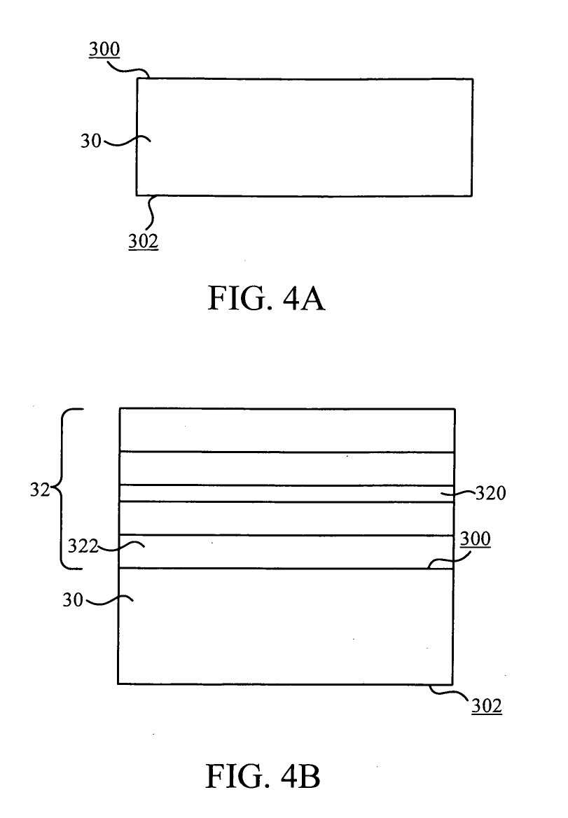

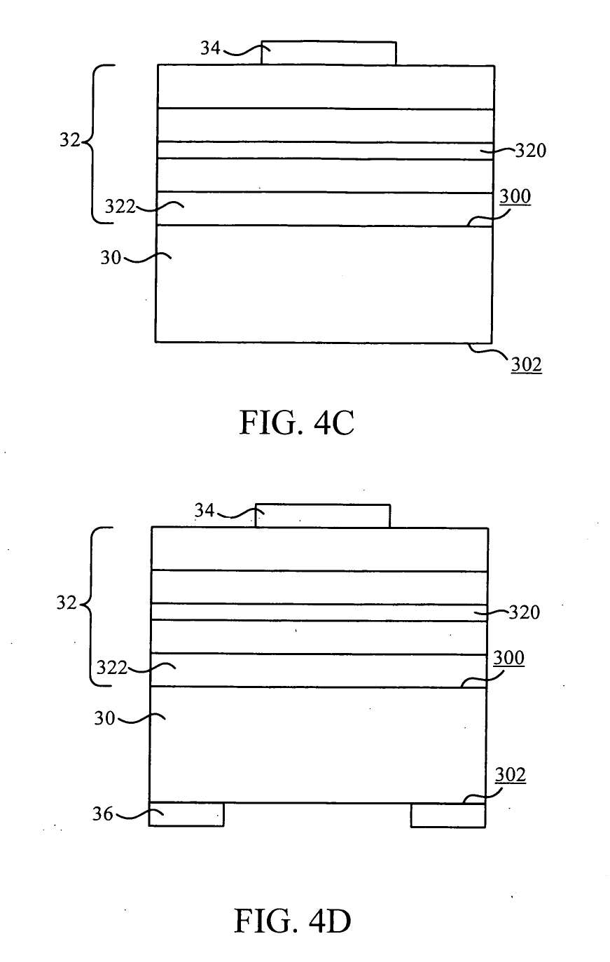

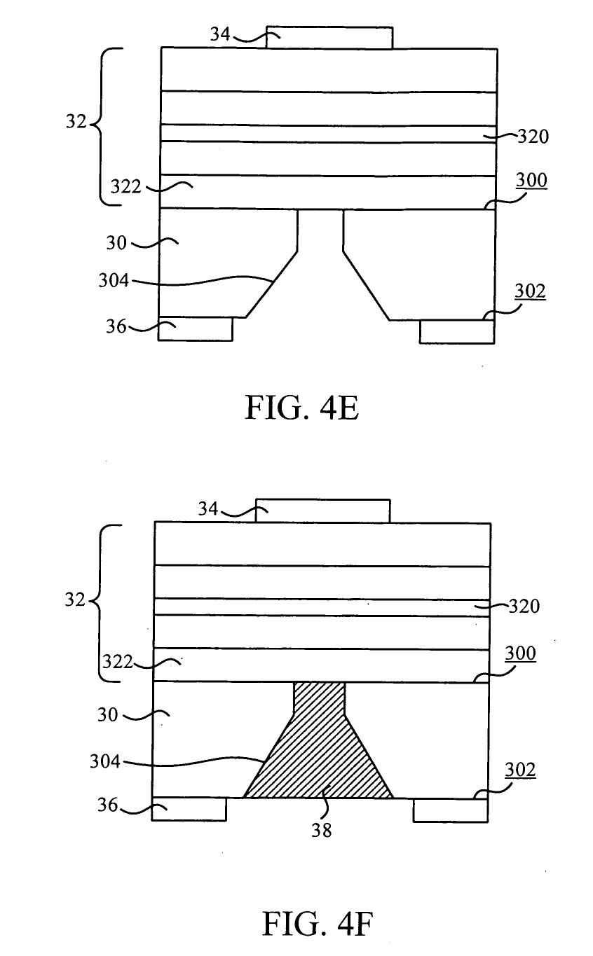

Please refer to FIG. 2 and FIG. 4A to FIG. 4F. FIG. 4A to FIG. 4F are section views illustrating a method for fabricating a semiconductor light-emitting device 3 according to another embodiment of the invention.

At first, as shown in FIG. 4A, a substrate 30 with an upper surface 300 and a lower surface 302 is prepared.

Secondly, as shown in FIG. 4B, a multi-layer structure 32 is formed on the upper surface 300 of the substrate 30.

Thirdly, as shown in FIG. 4C, a first electrode structure 34 is formed on the multi-layer structure 32.

Fourthly, as shown in FIG. 4D, a second electrode 36 is formed on the lower surface 302 of the substrate 30.

Fifthly, as shown in FIG. 4E, at least one formed-through hole 304 is formed in the substrate 30.

Finally, as shown in FIG. 4F, a thermal conductive material 38 is filled in the at least one formed-through hole 304. The effect of the thermal conductive material 38 is that the heat generated during operation of the semiconductor light-emitting device 3 can be conducted to the thermal conductive material 38 and dissipated therefrom.

In practice, the thermal conductive material 38 can be an electrical conductive or an electrical insulated material. For example, the thermal conductive material 38 can be, but not limited to, metal, ceramic, thermally conductive glue, or thermally conductive paste.

Compared to the prior art, the heat generated during the operation of the semiconductor light-emitting device according to the invention can be dissipated via the thermal conductive material to the outside from the inside of the semiconductor light-emitting device in an more efficient method. Therefore, the reliability and the lifetime of the semiconductor light-emitting device can be improved. The light-emitting efficiency of the semiconductor light-emitting device can be raise according to the property of the thermal conductive material. Furthermore, the semiconductor light-emitting device according to the invention can generate an advantage of low cost.

While the invention has been described in some preferred embodiments, it is understood that the words which have been used are words of description rather than words of limitation and that changes within the purview of the appended claims may be made without departing from the scope and spirit of the invention in its broader aspect.

What is claimed is:

1. A semiconductor light-emitting device, comprising:
a substrate having an upper surface and a lower surface, the substrate therein comprising at least one formed-through hole which is filled with a thermal conductive material;
a multi-layer structure formed on the upper surface of the substrate, the multi-layer structure comprising a light-emitting region;
a first electrode structure formed on the multi-layer structure; and
a second electrode structure formed on the lower surface of the substrate;
wherein a heat generated during operation of the semiconductor light-emitting device is conducted to the thermal conductive material and dissipated therefrom.

2. The semiconductor light-emitting device of claim 1, wherein the thermal conductive material is electrical conductive or electrical insulating.

3. The semiconductor light-emitting device of claim 2, wherein the thermal conductive material is one selected from a group consisting of metal, ceramics, thermal conductive glue, and thermal conductive paste.

4. The semiconductor light-emitting device of claim 1, wherein the at least one formed-through hole is formed by a dry etching process or a wet etching process.

5. The semiconductor light-emitting device of claim 1, wherein a bottom-most layer of the multi-layer structure is a multi-layer reflective layer.

6. The semiconductor light-emitting device of claim 5, wherein the multi-layer reflective layer is a Distributed Bragg Reflector (DBR).

7. The semiconductor light-emitting device of claim 1, wherein the substrate is formed of a material selected from a group consisting of SiO₂, Si, Ge, GaN, GaAs, GaP, AlN, sapphire, spinner, Al₂O₃, SiC, ZnO, MgO, LiAlO₂, LiGaO₂, and MgAl₂O₄.

8. A method for fabricating a semiconductor light-emitting device, comprising the following steps of:
preparing a substrate having an upper surface and a lower surface;
forming a multi-layer structure on the upper surface of the substrate, the multi-layer structure comprising a light-emitting region;
forming a first electrode structure on the multi-layer structure;
forming a second electrode structure on the lower surface of the substrate;
forming at least one formed-through hole on the substrate; and
filling the at least one formed-through hole with a thermal conductive material;
wherein a heat generated during operation of the semiconductor light-emitting device is conducted to the thermal conductive material and dissipated therefrom.

9. The method of claim 8, wherein the thermal conductive material is electrical conductive or electrical insulating.

10. The method of claim 9, wherein the thermally conductive material is one selected from a group consisting of metal, ceramic, thermally conductive glue, and thermally conductive paste.

11. The method of claim 8, wherein the at least one formed-through hole is formed by a dry etching process or a wet etching process.

12. The method of claim 8, wherein a bottom-most layer of the multi-layer structure is a multi-layer reflective layer.

13. The method of claim 12, wherein the multi-layer reflective layer is a Distributed Bragg Reflector (DBR).

14. The method of claim 8, wherein the substrate is formed of a material selected from a group consisting of SiO₂, Si, Ge, GaN, GaAs, GaP, AlN, sapphire, spinnel, Al₂O₃, SiC, ZnO, MgO, LiAlO₂, LiGaO₂, and MgAl₂O₄.
